(19) United States
(12) Patent Application Publication
(10) Pub. No.: US 2026/0362638 A1
(43) Pub. Date: Nov. 12, 2026

(54) THERMAL MANAGEMENT SYSTEM

(71) Applicant: Tyco Fire & Security GmbH, Neuhausen am Rheinfall (CH)

(72) Inventors: Ian M. Casper, York, PA (US); Thomas P. Carter, New Freedom, PA (US); Jeb W. Schreiber, Stewartstown, PA (US); Bryson L. Sheaffer, York, PA (US); Jonathan D. Douglas, Mequon, WI (US)

(21) Appl. No.: 19/669,601

(22) Filed: May 6, 2026

Related U.S. Application Data
(60) Provisional application No. 63/803,399, filed on May 9, 2025.
(60) Provisional application No. 63/819,418, filed on Jun. 6, 2025.
(60) Provisional application No. 63/922,885, filed on Nov. 21, 2025.

(51) Int. Cl. H05K 7/20

(52) U.S. Cl. CPC H05K 7/20254; H05K 7/20272; H05K 7/2039; H05K 7/20772

(57) ABSTRACT

A thermal management system includes: a heat source configured to provide thermal energy; a cooling circuit configured to deliver a first heat transfer fluid; and a housing including a contact wall engaging the heat source and a dividing wall offset from the contact wall. The housing defines: a heat spreader chamber extending from the contact wall to the dividing wall and containing a second heat transfer fluid; a cold plate chamber separated from the heat spreader chamber by the dividing wall; and a fluid aperture fluidly coupling the cold plate chamber to the cooling circuit. The second heat transfer fluid is configured to transfer the thermal energy from the heat source to the first heat transfer fluid within the cold plate chamber. The dividing wall extends continuously from the heat spreader chamber to the cold plate chamber.

### CROSS-REFERENCE TO RELATED PATENT APPLICATIONS

This application claims the benefit of and priority to U.S. Provisional Application No. 63/803,399, filed on May 9, 2025, U.S. Provisional Application No. 63/819,418, filed on Jun. 6, 2025, and U.S. Provisional Application No. 63/922,885, filed on Nov. 21, 2025, the entire disclosures of which are hereby incorporated by reference herein.

### BACKGROUND

The present disclosure relates generally to heating, ventilation, and air conditioning (HVAC) systems for data centers. The present disclosure relates more particularly to cooling systems for data center equipment that generate heat during operation (e.g., servers, racks, blades, power supplies, etc.).

Data centers typically include racks of servers or other data center equipment that generate a substantial amount of heat during operation. Some data center cooling systems use fans to circulate cooled air through the server racks and provide cooling to the heat-generating equipment. Other data center cooling systems circulate a liquid coolant (e.g., water, glycol, etc.) to the racks to draw heat directly from the heat-generating equipment or use a combination of air and liquid cooling.

As data centers expand to support the rapid growth of cloud computing, artificial intelligence (AI), and high-performance computing (HPC), data centers need effective, energy-efficient cooling solutions to handle rising power densities while minimizing environmental impact. Conventional data center cooling infrastructures are often inadequate to provide sufficient cooling to modern data centers due to significantly higher power densities and heat generated relative to traditional data centers. For example, each central processing unit (CPU) in a traditional data center server may have a thermal design power (TDP) of 250-350 Watts, whereas a modern data center server may include several graphics processing units (GPUs) with TDPs of 1.2 kW each to support AI applications. A modern data center server with 8 GPUs and 2 CPUs may have a total TDP of 10,000 Watts per AI server, as compared to 700 Watts for traditional servers with two CPUs. Conventional data center cooling infrastructures often cannot support the high power densities and thermal loads of modern data centers.

Additionally, conventional data center cooling systems are often designed to provide the same amount of cooling (e.g., airflow, water flow, etc.) to all server racks in a given data center room or aisle. This can lead to inefficiencies (e.g., excess cooling, increased energy consumption, etc.) if the heat load generated by the data center equipment is concentrated in a subset of the server racks because the cooling system will operate to ensure that the hottest server rack is kept within temperature limits, and thus provides more cooling than necessary to the server racks that are generating a lesser heat load. This problem is exacerbated in modern data centers which have high disparities in TDP between server racks or individual servers used for different purposes (e.g., conventional CPU-based computing vs. GPU-based AI applications). It would be desirable to provide an improved cooling infrastructure for modern data centers that addresses these and other deficiencies of conventional data center cooling systems.

### SUMMARY

At least one embodiment relates to a thermal management system including: a heat source configured to provide thermal energy; a cooling circuit configured to deliver a first heat transfer fluid; and a housing including a contact wall engaging the heat source and a dividing wall offset from the contact wall, the housing defining: a heat spreader chamber extending from the contact wall to the dividing wall and containing a second heat transfer fluid; a cold plate chamber separated from the heat spreader chamber by the dividing wall; and a fluid aperture fluidly coupling the cold plate chamber to the cooling circuit. The second heat transfer fluid is configured to transfer the thermal energy from the heat source to the first heat transfer fluid within the cold plate chamber. The dividing wall extends continuously from the heat spreader chamber to the cold plate chamber.

In some embodiments, the housing further includes a side wall extending away from the dividing wall, and the side wall and the dividing wall are formed as a single, continuous piece of material.

In some embodiments, the side wall partially defines the heat spreader chamber.

In some embodiments, the side wall, the dividing wall, and the contact wall are formed as the single, continuous piece of material.

In some embodiments, the side wall partially defines the cold plate chamber.

In some embodiments, the housing further includes a top wall offset from the dividing wall, the cold plate chamber extends from the top wall to the dividing wall, and the side wall, the dividing wall, and the contact wall are formed as the single, continuous piece of material.

In some embodiments, the thermal management system further includes an end cap coupled to the housing and partially defining the heat spreader chamber and the cold plate chamber.

In some embodiments, the housing further includes a top wall offset from the dividing wall, the cold plate chamber extends from the top wall to the dividing wall, the side wall extends from the top wall to the contact wall, and the side wall, the dividing wall, the contact wall, and the top wall are formed as the single, continuous piece of material.

In some embodiments, the contact wall has a first thickness, and the dividing wall has a second thickness less than the first thickness.

In some embodiments, the contact wall is positioned below the dividing wall, and the contact wall includes an interface section that engages the heat source and an angled section that extends upward and laterally outward from the interface section.

Another embodiment relates to a thermal management system including: a heat source configured to provide thermal energy; a heat spreader including a contact wall engaging the heat source, the heat spreader defining a heat spreader chamber containing a first heat transfer fluid; a cold plate coupled to the heat spreader and defining a cold plate chamber configured to be fluidly coupled to a cooling circuit such that the first heat transfer fluid transfers the thermal energy from the heat source to a second heat transfer fluid within the cold plate chamber; a dividing wall extending between the heat spreader chamber and the cold plate chamber; and a protrusion extending into the heat spreader chamber.

In some embodiments, the protrusion is coupled to the dividing wall and extends toward the contact wall.

In some embodiments, the protrusion is a support column extending across the heat spreader chamber from the dividing wall to the contact wall.

In some embodiments, the protrusion is a first protrusion, and the thermal management system further includes a second protrusion coupled to the dividing wall and extending into the cold plate chamber.

In some embodiments, the cold plate includes a top wall opposite the dividing wall, and the second protrusion extends across the cold plate chamber from the dividing wall to the contact wall.

In some embodiments, the protrusion is coupled to the contact wall and extends toward the dividing wall.

In some embodiments, the heat spreader further includes a side wall extending between the contact wall and the dividing wall, and the protrusion is a rib extending from the side wall into the heat spreader chamber.

In some embodiments, the dividing wall is formed as a single, continuous piece of material that partially defines both the heat spreader chamber and the cold plate chamber.

Another embodiment relates to a thermal management system including: a heat source configured to provide thermal energy; a cooling circuit configured to deliver a first heat transfer fluid; a heat spreader engaging the heat source and containing a second heat transfer fluid; a cold plate including a first wall coupled to the heat spreader, a second wall offset from the first wall to define a fluid chamber fluidly coupled to the cooling circuit such that the second heat transfer fluid is configured to transfer the thermal energy from the heat source to the first heat transfer fluid within the fluid chamber; and a protrusion coupled to the first wall and extending into the fluid chamber toward the second wall.

In some embodiments, the protrusion is a support column extending across the fluid chamber from the first wall to the second wall.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF THE FIGURES

The disclosure will become more fully understood from the following detailed description, taken in conjunction with the accompanying figures, wherein like reference numerals refer to like elements, in which:

FIG. 1 is a schematic block diagram of a thermal management system, according to an exemplary embodiment.

FIG. 2 is a perspective view of a heat spreader of a thermal management system, according to an exemplary embodiment.

FIG. 3 is a schematic block diagram of a thermal management system, according to an exemplary embodiment.

FIG. 4 is a side section view of a heat spreader of a thermal management system, according to an exemplary embodiment.

FIG. 5-11 are side views of thermal management systems, according to various exemplary embodiments.

FIG. 12 is a side view of a blade server including a thermal management system, according to an exemplary embodiment.

FIGS. 13 and 14 are side views of thermal management systems, according to various exemplary embodiments.

FIG. 15 is an exploded view of a thermal management system, according to an exemplary embodiment.

FIG. 16-20 are section views of housings for thermal management systems, according to various exemplary embodiments.

FIG. 21 is a top view of a wall of a housing for a thermal management system, according to an exemplary embodiment.

FIG. 22 is a perspective view of a wall of a housing for a thermal management system, according to an exemplary embodiment.

FIGS. 23 and 24 are section views of housings for thermal management systems, according to various exemplary embodiments.

FIG. 25 is a top section view of the housing of FIG. 24.

FIGS. 26 and 27 are section views of housings for thermal management systems, according to various exemplary embodiments.

### DETAILED DESCRIPTION

Before turning to the figures, which illustrate certain exemplary embodiments in detail, it should be understood that the present disclosure is not limited to the details or methodology set forth in the description or illustrated in the figures. It should also be understood that the terminology used herein is for the purpose of description only and should not be regarded as limiting.

### Thermal Management System

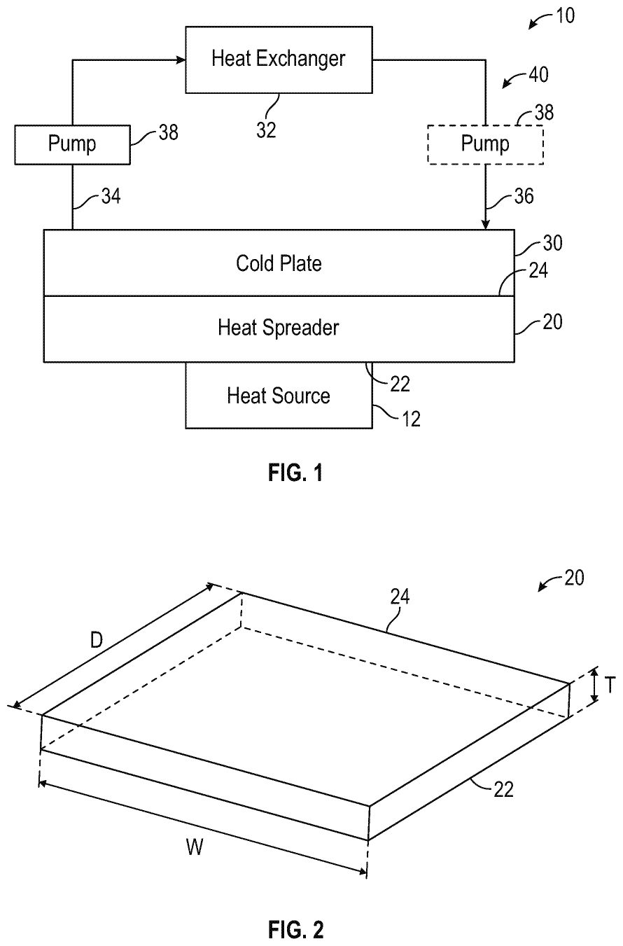

Referring to FIG. 1, a thermal management system or cooling system is shown as system 10 according to an exemplary embodiment. The system 10 may be utilized within a server or other electronic device to cool one or more components of the server that generate thermal energy during operation. The system 10 may transfer the thermal energy from the components to the surrounding environment or to a remote location, facilitating efficient, low-temperature operation of the components. Beneficially, the arrangement of the system 10 may provide a thin or low-profile assembly that facilitates increasing the density of the server layout, adding components to a server of a given size while maintaining adequate cooling performance.

The system 10 includes a heated component, integrated circuit, microchip, chip, or processor, shown as heat source 12. The heat source 12 may be any component that generates, emits, produces, or otherwise outputs thermal energy during operation. By way of example, the heat source 12 may receive electrical energy and perform computations or processing, generating thermal energy due to electrical resistance. The heat source 12 may include a component of a server or other computing device. By way of example, the heat source 12 may be a graphics processing unit (“GPU”), a central processing unit (“CPU”), or another type of processor. The heat source 12 may be or include a semiconductor mounted on a substrate with conductive leads, such as a printed circuit board.

The system 10 further includes a heat exchanger, heat spreader, heat pipe, thermal siphon, ground plane, closed thermal transfer system, or passive thermal transfer system, shown as heat spreader 20. The heat spreader 20 is configured to receive and transfer thermal energy generated by the heat source 12. The heat spreader 20 may perform this heat transfer passively (e.g., without a mechanical energy input or electrical energy input). By way of example, the heat spreader 20 may transfer the thermal energy without requiring a pump or other device that would actively circulate a fluid or other heat transfer medium.

As shown in FIGS. 1 and 2, the heat spreader 20 has a first surface, heat conduction surface, bottom surface, or thermal energy input surface, shown as conduction surface 22, and a second surface, heat ejection surface, heat rejection surface, top surface, or thermal energy output surface, shown as rejection surface 24. The conduction surface 22 is configured to engage the heat source 12 to receive the thermal energy from the heat source 12. The heat spreader 20 is configured to transfer the thermal energy from the conduction surface 22 to the rejection surface 24. The thermal energy may then be ejected or rejected from the heat spreader 20 through the rejection surface 24.

As shown in FIG. 2, the conduction surface 22 and the rejection surface 24 extend substantially parallel to one another, such that the heat spreader 20 is configured as a thin, flat plate (e.g., a heat spreader plate). The heat spreader 20 has a thickness T measured vertically between the conduction surface 22 and the rejection surface 24. The heat spreader 20 has a width W and a depth D measured perpendicular to one another and to the thickness T. In some embodiments, the thickness T is smaller than the width W and the depth D, such that the thickness T is the smallest dimension of the heat spreader 20.

As shown in FIG. 2, the conduction surface 22 and the rejection surface 24 are arranged opposite one another, such that the conduction surface 22 and the rejection surface 24 face away from the heat spreader 20 in opposite directions (e.g., downward and upward, respectively). Additionally, both the conduction surface 22 and the rejection surface 24 are flat. Accordingly, the thermal energy is transferred along the thickness T of the heat spreader 20, between the heat spreader 20 and the conduction surface 22. In other embodiments, the conduction surface 22 and the rejection surface 24 both face in the same direction. In yet other embodiments, the heat spreader 20 includes multiple conduction surfaces 22 and/or multiple rejection surfaces 24.

As shown in FIG. 1, the system 10 further includes a heat sink, heat exchanger, or chill plate, shown as cold plate 30. The cold plate 30 engages the rejection surface 24, such that the cold plate 30 receives the thermal energy ejected by the heat spreader 20. The cold plate 30 then dissipates, ejects, or transfers the thermal energy to the surrounding environment (e.g., directly or indirectly through another heat exchanger). Accordingly, the thermal energy from the heat source 12 is transferred to the cold plate 30 by the heat spreader 20 and subsequently dissipated. In this way, the heat spreader 20 and the cold plate 30 facilitate cooling the heat source 12.

As shown in FIGS. 1 and 2, the heat source 12 engages a first area of the conduction surface 22, and the cold plate 30 engages a second area of the rejection surface 24. As shown, the surface area of the heat source 12 that engages the conduction surface 22 is smaller than the surface area of the cold plate 30 that engages the rejection surface 24, such that the first area is smaller than the second area. Beneficially, the heat spreader 20 may facilitate receiving concentrated thermal energy through a small area (i.e., the first area) and spreading the thermal energy over a larger area (i.e., the second area) before transferring to the cold plate 30. By spreading out the thermal energy over a larger area, the heat transfer rate of the thermal energy from the heat source 12 to the cold plate 30 may be increased.

### Cold Plate Variations

In some embodiments, the cold plate 30 is formed from a material having a high thermal conductivity. By way of example, the cold plate 30 may be formed from (e.g., include, be made entirely from, etc.) copper or aluminum. By utilizing a material with a high thermal conductivity, the cold plate 30 may efficiently transfer thermal energy away from the heat spreader 20.

In the configuration of FIG. 1, the cold plate 30 is cooled using a cooling fluid, single-phase heat transfer medium, heat transfer fluid, or coolant (e.g., a mixture of water, glycol, and a liquid dielectric, etc.) that transfers thermal energy out of the cold plate 30. The cold plate 30 is in fluid communication with (e.g., is fluidly coupled to) a heat exchanger (e.g., a radiator, a chiller, etc.), shown as heat exchanger 32. By way of example, the heat exchanger 32 may be part of a cooling system of a data center. A first conduit (e.g., hose, pipe, etc.), shown as supply line 34, extends between an outlet of the cold plate 30 and an inlet of the heat exchanger 32. A second conduit, shown as return line 36, extends between an outlet of the heat exchanger 32 and an inlet of the cold plate 30. An actuator, shown as pump 38, is fluidly coupled to the cold plate 30 and the heat exchanger 32. A first position of the pump 38, shown in solid lines, places the pump 38 along the supply line 34 (e.g., upstream of the heat exchanger 32). A second position of the pump 38, shown in dashed lines, places the pump 38 along the return line 36 (e.g., downstream of the heat exchanger 32. The pump 38 may be positioned in the first position, in the second position, or the system 10 may include both a pump 38 in the first position and a pump 38 in the second position. Together, the cold plate 30, the heat exchanger 32, the supply line 34, the return line 36, and the pump 38 form a single-phase cooling circuit or loop, shown as coolant circuit 40.

In operation, the pump 38 drives the coolant to circulate throughout the coolant circuit 40 and remove thermal energy from the cold plate 30. Coolant enters the inlet of the cold plate 30 and absorbs thermal energy from the cold plate 30. This high-temperature coolant then passes through the supply line 34 to the heat exchanger 32. The heat exchanger 32 then transfers the thermal energy from the coolant to the surrounding environment. The heat exchanger 32 may transfer the thermal energy to the surrounding environment directly (e.g., through a radiator in communication with air of the surroundings). Alternatively, the heat exchanger 32 may transfer the thermal energy to the surrounding environment indirectly (e.g., the heat exchanger 32 includes a chiller that transfers the thermal energy to a secondary cooling loop, which in turn transfers the thermal energy to the surrounding environment). The low-temperature coolant then returns to an inlet of the cold plate 30.

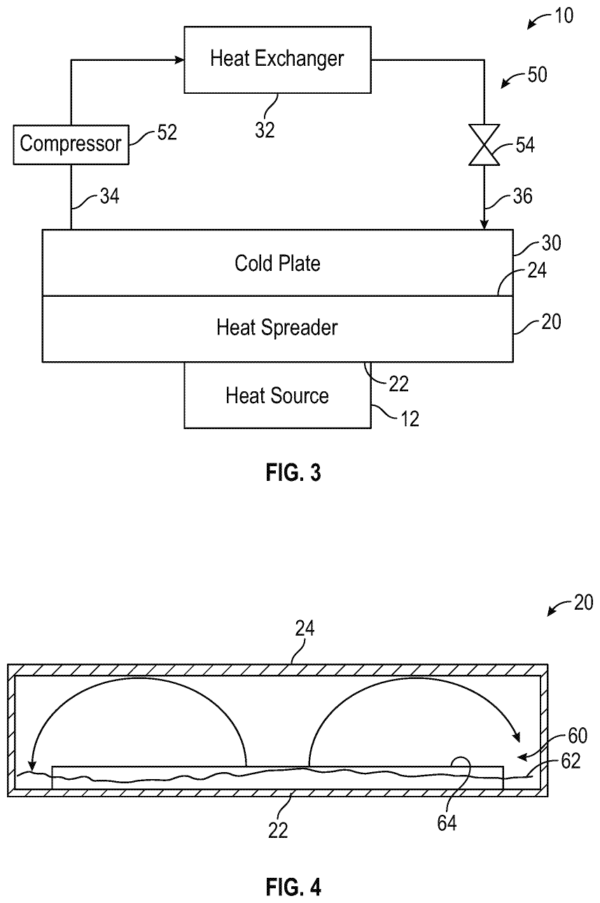

Referring to FIG. 3, an alternative embodiment of the system 10 is shown in which the cold plate 30 is cooled using a two-phase heat transfer medium, heat transfer fluid, or refrigerant (e.g., carbon dioxide (CO₂)). In the system 10 of FIG. 3, the coolant circuit 40 is omitted, and the cold plate 30 and the heat exchanger 32 are instead part of a two-phase cooling circuit or loop, shown as refrigeration circuit 50. In the embodiment of FIG. 3, the cold plate 30 may include or be configured as an evaporator, and the heat exchanger 32 may include or be configured as a condenser. By way of example, the heat exchanger 32 may be part of cooling system of a data center, such as the data center cooling system described in U.S. Provisional Patent Application No. 63/818,920 filed Jun. 6, 2025, the entire disclosure of which is incorporated by reference herein. The refrigeration circuit 50 further includes an actuator, shown as compressor 52, that is positioned along the supply line 34, and a metering device, shown as expansion valve 54, that is positioned along the return line 36.

In operation, the compressor 52 forces the refrigerant to circulate throughout the refrigeration circuit 50 to perform a refrigeration cycle and cool the cold plate 30. The cold plate 30 receives a volume of refrigerant as a low-pressure liquid from the return line 36. The cold plate 30 transfers thermal energy to the refrigerant, converting the refrigerant to a low-pressure gas and cooling the cold plate 30. The refrigerant passes to the compressor 52, where the refrigerant is compressed to a high pressure. The high-pressure gas is received by the heat exchanger 32 (e.g., configured as a condenser), and the heat exchanger 32 transfers thermal energy from the refrigerant to the surrounding environment. The refrigerant leaves the heat exchanger 32 as a high-pressure liquid and passes to the expansion valve 54. The expansion valve 54 expands the refrigerant, returning the refrigerant back to the cold plate 30 as a low-pressure liquid.

In other embodiments, the heat exchanger 32 is omitted, and the cold plate 30 transfers the thermal energy from the heat spreader 20 directly to the surrounding environment. By way of example, the cold plate 30 may include heat transfer fins that contact air flowing around the cold plate 30 to transfer thermal energy to the surrounding air. In such an embodiment, the system 10 may include a fan that forces air toward the cold plate 30.

### Heat Spreader Variations

In some embodiments, the heat spreader 20 is configured as a self-contained, passive, two-phase heat transfer device (e.g., a thermal siphon, a ground plane, etc.) that utilizes a heat transfer fluid to facilitate the transfer of thermal energy from the heat source 12 to the cold plate 30. Such a heat spreader 20 may operate passively, without the input of mechanical or electrical energy (e.g., the heat spreader 20 may operate based on a temperature differential between the conduction surface 22 and the rejection surface 24). An example of such a heat spreader 20 is illustrated in FIG. 4.

As shown in FIG. 4, the heat spreader 20 defines a sealed interior chamber or heat spreader chamber, shown as fluid chamber 60, containing a heat transfer fluid 62 (e.g., a low-pressure refrigerant). The fluid chamber 60 may be permanently sealed, such that the amount of heat transfer fluid 62 in the fluid chamber 60 is fixed (e.g., the heat transfer fluid 62 does not enter or leave the fluid chamber 60). A capillary member or liquid return, shown as wick 64, is positioned within the fluid chamber 60 and extends along an interior side of the conduction surface 22.

In operation, the heat transfer fluid 62 collects along the interior side the conduction surface 22 in a liquid form. Thermal energy from the heat source 12 passes through the conduction surface 22 and into the heat transfer fluid 62. The heat transfer fluid 62 consumes this thermal energy and forms a vapor (e.g., changes phase, boils, evaporates, etc.). The vapor spreads throughout the fluid chamber 60 and comes into contact with the interior side of the rejection surface 24. Due to the cooling effect of the cold plate 30, the rejection surface 24 is cooler than the vapor. Accordingly, thermal energy from the heat transfer fluid 62 is transferred through the rejection surface 24 and to the cold plate 30. As the heat transfer fluid 62 is cooled, the heat transfer fluid 62 may return to a liquid state (e.g., change phase) and fall toward the conduction surface 22 and contact the wick 64. Through capillary action, the wick 64 may draw or otherwise transfer the heat transfer fluid 62 back toward the heat source 12. This cycle may repeat continuously to facilitate the transfer of thermal energy between the conduction surface 22 and the rejection surface 24.

Because the vapor expands throughout the fluid chamber 60 when heated, the heat transfer fluid 62 may evenly heat the entirety of the heat spreader 20. Accordingly, while the rejection surface 24 is shown as being a top surface of the heat spreader 20, any surface of the heat spreader 20 may act as the rejection surface 24. By way of example, the conduction surface 22 and the rejection surface 24 may both be positioned along a bottom side of the heat spreader 20 (e.g., as shown in FIG. 10), with the conduction surface 22 and the rejection surface 24 being laterally offset from one another. The gaseous expansion of the vapor may permit the heated vapor to move laterally to reach this rejection surface 24, even though the rejection surface 24 is not positioned along a top side of the heat spreader 20.

In other embodiments, the heat spreader 20 does not utilize a two-phase configuration (e.g., maintains a single phase throughout operation). By way of example, the heat spreader 20 may be a single, continuous piece of solid material. In such an embodiment, the heat spreader 20 may be made from a material having a high thermal conductivity. By way of example, the heat spreader 20 may be formed from (e.g., include, be made entirely from, etc.) copper or aluminum. By utilizing a material with a high thermal conductivity, the heat spreader 20 may efficiently transfer thermal energy between the heat source 12 and the cold plate 30.

### System Arrangements

While several different configurations of the components of the system 10 have been described herein, it should be understood that the system 10 may utilize any combination of the heat sources 12, the heat spreaders 20, and the cold plates 30 described herein. By way of example, the system 10 may utilize a CPU as the heat source 12, the heat spreader 20 of FIG. 4, and the cold plate 30 in communication with the coolant circuit 40 of FIG. 1. By way of another example, the system 10 may utilize a GPU as the heat source 12, a heat spreader 20 made of solid copper, and the cold plate 30 in communication with the refrigeration circuit 50 of FIG. 3. Accordingly, any heat source 12 may be substituted for another heat source 12 described herein, any heat spreader 20 may be substituted for another heat spreader 20 described herein, and any cold plate 30 may be substituted for another cold plate 30 described herein.

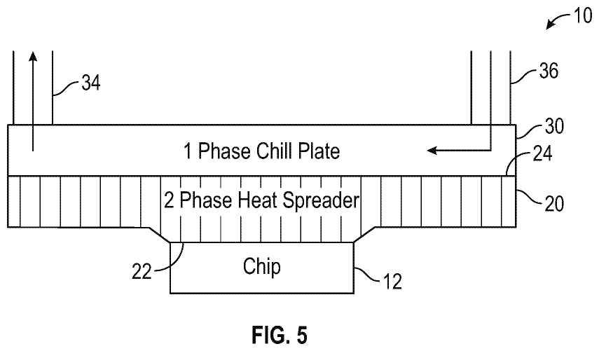

Referring to FIG. 5, the system 10 is shown according to an exemplary embodiment. The system 10 includes a heat source 12 configured as a chip (e.g., a CPU or GPU). The system 10 includes a heat spreader 20 configured as a two-phase heat spreader (e.g., the heat spreader 20 of FIG. 4). The system 10 includes a cold plate 30 that is actively cooled by a fluid (e.g., by the coolant circuit 40 or by the refrigeration circuit 50).

As shown, the heat source 12 is narrower than the cold plate 30, such that the heat spreader 20 spreads thermal energy from the heat source 12 laterally across the entirety of the cold plate 30. The heat source 12, the heat spreader 20, and the cold plate 30 are substantially laterally centered relative to one another. Accordingly, the heat spreader 20 and the cold plate 30 laterally overhang beyond the heat source 12 in both a leftward direction and a rightward direction. The system 10 may have a similar arrangement in the forward/backward direction (e.g., into the page as shown in FIG. 5), such that the heat spreader 20 and the cold plate 30 may overhang beyond the heat source 12 in both a forward direction and a rearward direction. In some embodiments, the area of the conduction surface 22 in communication with the heat source 12 is smaller than the area of the rejection surface 24 in communication with the cold plate 30. The heat spreader 20 may accordingly spreading the thermal energy from the heat source 12 across a greater area of the cold plate 30. The heat source 12 is positioned along a bottom side of the heat spreader 20, and the cold plate 30 is positioned along a top side of the heat spreader 20, such that the heat spreader 20 is sandwiched (e.g., extends vertically) between the heat source 12 and the cold plate 30.

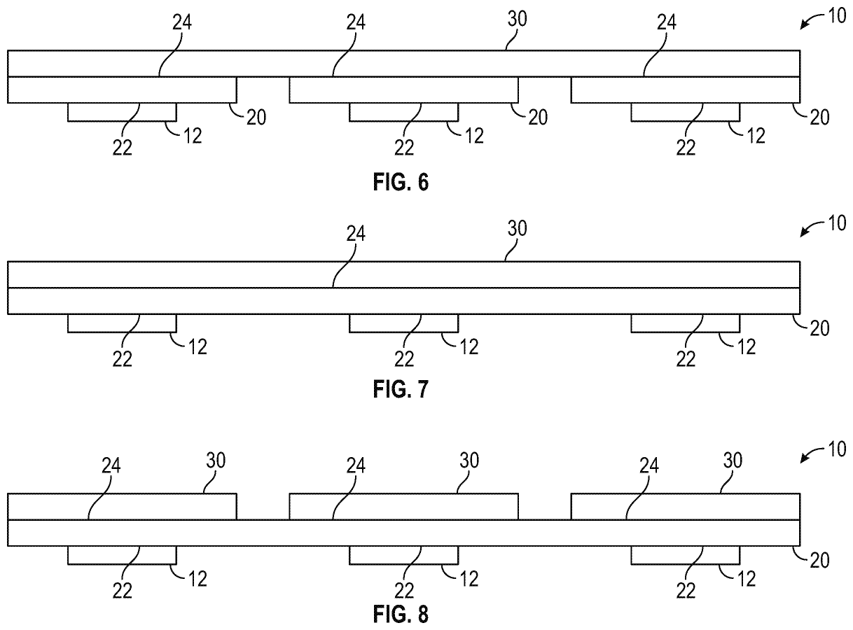

FIG. 6-14 illustrate various layouts of the system 10. In each of these embodiments, the heat source 12, the heat spreader 20, and the cold plate 30 may represent any of the heat source 12, the heat spreader 20, or the cold plate 30 described herein.

Referring to FIG. 6, the system 10 is shown according to an exemplary embodiment. In the embodiment of FIG. 6, the system 10 includes three heat sources 12, three heat spreaders 20, and a single cold plate 30. Each heat source 12 is directly coupled to a bottom side of one of the heat spreaders 20. Each heat spreader 20 is directly coupled to a bottom side of the cold plate 30. Accordingly, the heat spreaders 20 each transfer thermal energy from a corresponding heat source 12 to the cold plate 30. Beneficially, in the arrangement of FIG. 6, a single cold plate 30 may be used to service the cooling of multiple heat sources 12.

Referring to FIG. 7, the system 10 is shown according to an exemplary embodiment. In the embodiment of FIG. 7, the system 10 includes three heat sources 12, a single heat spreader 20, and a single cold plate 30. Each heat source 12 is directly coupled to a bottom side of the heat spreader 20. The heat spreader 20 is directly coupled to a bottom side of the cold plate 30. Accordingly, the heat spreader 20 transfers thermal energy from all of the heat sources 12 to the cold plate 30. Beneficially, in the arrangement of FIG. 6, a single cold plate 30 and a single heat spreader 20 may be used to service the cooling of multiple heat sources 12.

Referring to FIG. 8, the system 10 is shown according to an exemplary embodiment. In the embodiment of FIG. 8, the system 10 includes three heat sources 12, a single heat spreader 20, and three cold plates 30. Each heat source 12 is directly coupled to a bottom side of the heat spreader 20. The heat spreader 20 is directly coupled to a bottom side of each cold plate 30. Accordingly, the heat spreader 20 transfers thermal energy from all of the heat sources 12 to each of the cold plates 30. Beneficially, in the arrangement of FIG. 6, a single heat spreader 20 may be used to service the cooling of multiple heat sources 12.

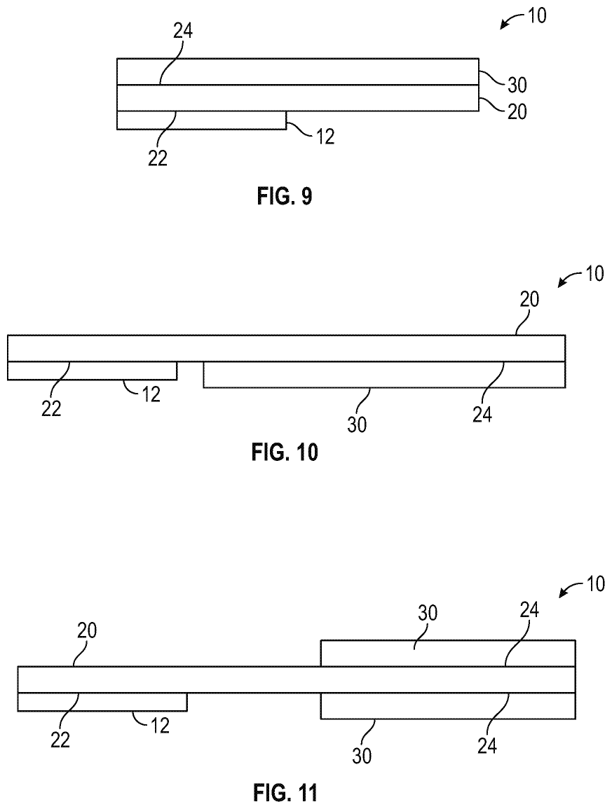

Referring to FIG. 9, the system 10 is shown according to an exemplary embodiment. In the embodiment of FIG. 9, the heat source 12 is narrower than the cold plate 30, such that the heat spreader 20 spreads thermal energy from the heat source 12 laterally across the entirety of the cold plate 30. A center of the heat source 12 is laterally offset from the centers of the heat spreader 20 and the cold plate 30, and the heat spreader 20 and the cold plate 30 are substantially laterally centered relative to one another. Accordingly, the heat spreader 20 and the cold plate 30 laterally overhang beyond the heat source 12 in a rightward direction. The heat source 12 is positioned along a bottom side of the heat spreader 20, and the cold plate 30 is positioned along a top side of the heat spreader 20, such that the heat spreader 20 is sandwiched (e.g., extends vertically) between the heat source 12 and the cold plate 30.

Referring to FIG. 9, the system 10 is shown according to an exemplary embodiment. In the embodiment of FIG. 9, the system 10 includes a heat source 12, a heat spreader 20, and a cold plate 30. The heat source 12 is narrower than the cold plate 30, such that the heat spreader 20 spreads thermal energy from the heat source 12 laterally across the entirety of the cold plate 30. The heat source 12 is laterally offset from the centers of the heat spreader 20 and the cold plate 30, and the heat spreader 20 and the cold plate 30 are substantially laterally centered relative to one another. Accordingly, the heat spreader 20 and the cold plate 30 laterally overhang beyond the heat source 12 in a rightward direction. The heat source 12 is positioned along a bottom side of the heat spreader 20, and the cold plate 30 is positioned along a top side of the heat spreader 20, such that the heat spreader 20 is sandwiched (e.g., extends vertically) between the heat source 12 and the cold plate 30.

Referring to FIG. 10, the system 10 is shown according to an exemplary embodiment. In the embodiment of FIG. 10, a heat source 12 and a cold plate 30 are both positioned along a bottom side of a heat spreader 20. Accordingly, the heat spreader 20 spreads thermal energy from the heat source 12 laterally toward the cold plate 30. The heat source 12 is laterally offset from the cold plate 30 to prevent the heat source 12 from overlapping the cold plate 30.

Referring to FIG. 11, the system 10 is shown according to an exemplary embodiment. In the embodiment of FIG. 11, a heat source 12 and a first cold plate 30 are both positioned along a bottom side of a heat spreader 20. A second cold plate 30 is positioned along a top side of the heat spreader 20. Accordingly, the heat spreader 20 spreads thermal energy from the heat source 12 laterally toward both of the cold plates 30. Advantageously, the system 10 is able to utilize multiple cold plates 30 to dissipate thermal energy from one heat source 12, increasing the rate at which the thermal energy can be dissipated.

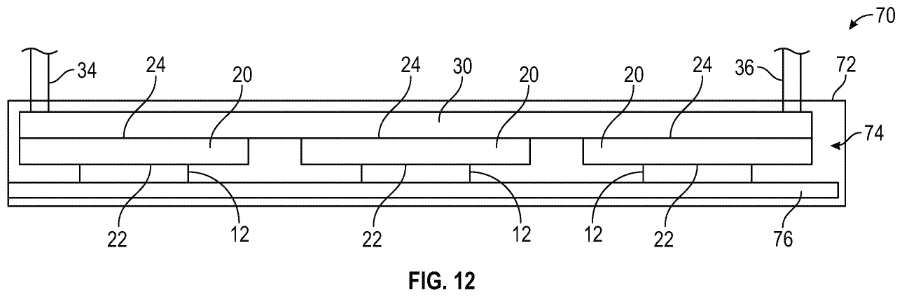

Referring to FIG. 12, the system 10 is shown being applied as a cooling system for a computing system or server module, shown as blade server 70. The blade server 70 may be a modular computing assembly that fits into a larger server rack or chassis. The server system may utilize multiple blade servers 70 in cooperation with one other to perform complex computing tasks.

As shown, the blade server 70 includes a frame or enclosure, shown as housing 72. The housing 72 defines an enclosed volume, shown as housing volume 74, that receives the system 10. The blade server 70 further includes a substrate or circuit board, shown as motherboard 76, that supports three heat sources 12. The motherboard 76 may facilitate communication between the heat sources 12. The heat sources 12 may each be CPUs, GPUs, or other semiconductors that communicate with the motherboard 76.

As shown in FIG. 12, the system 10 has a similar arrangement to the system 10 of FIG. 6. During operation of the blade server 70, the heat sources 12 each consume electrical energy and produce thermal energy that is discharged into the housing volume 74. The thermal energy is transferred by the heat spreaders 20 to a common cold plate 30. The thermal energy may then be removed by circulating a heat transfer fluid (e.g., coolant, refrigerant, etc.) through the cold plate 30. The supply line 34 and the return line 36 may fluidly couple the cold plate 30 to a heat exchanger 32 that is positioned remote from the blade server 70. Accordingly, the system 10 may facilitate cooling the blade server 70.

The plate shapes of the heat spreaders 20 and the cold plate 30 permit the system 10 to have a small overall thickness (e.g., measured vertically). However, due to the inclusion of the heat spreaders 20 to distribute the thermal energy from the heat source 12 across the cold plate 30, the system 10 may still provide significant cooling performance to the blade server 70. The system 10 is accordingly able to cool the blade server 70 in a much thinner package than other types of cooling systems, such as fans that would force air through housing volume 74. The system 10 may permit a reduction in the overall size of the blade server 70 relative to other cooling systems, increasing the density of the blade server 70 and permitting additional blade servers 70 to fit into a given size of server rack.

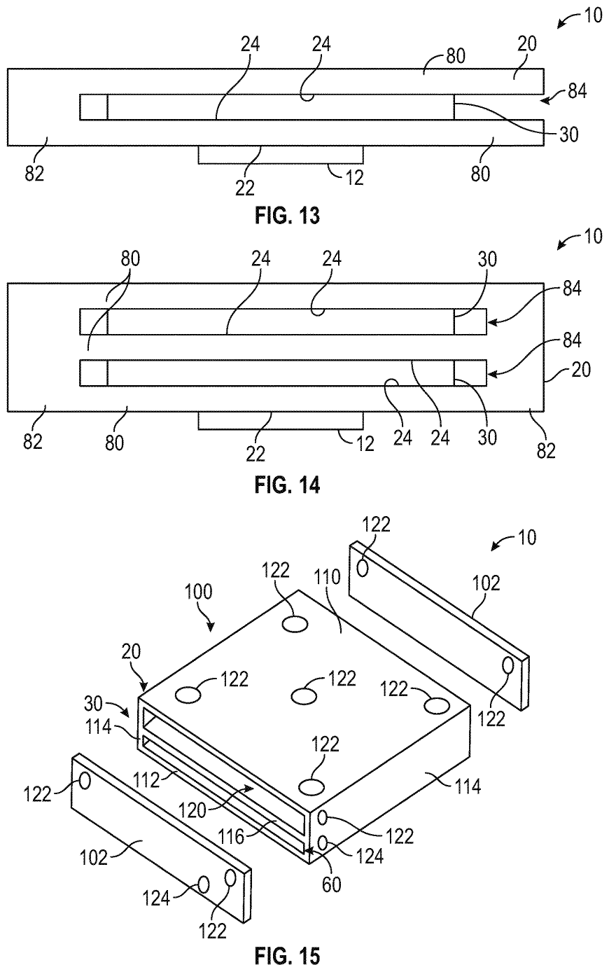

Referring to FIG. 13, the system 10 is shown according to an exemplary embodiment. In the embodiment of FIG. 13, the heat spreader 20 is shaped to include a series of flat protrusions, plates, slabs, or partitions, shown as fins 80, that are connected to one another by a connection portion or base, shown as bridge 82. The bridge 82 is fluidly coupled to the fins 80, such that the fins 80 and the bridge 82 form a continuous fluid chamber 60. A slot, groove, notch, passage, or recess, shown as cold plate slot 84, is defined between the fins 80. The end of the cold plate slot 84 nearest the bridge 82 is enclosed by the bridge 82, and the end of the cold plate slot 84 farthest from the bridge 82 is open.

A cold plate 30 is received within the cold plate slot 84 between the fins 80, such that a first fin 80 has a first rejection surface 24 that engages a bottom side of the cold plate 30 and a second fin 80 has a second rejection surface 24 that engages a top side of the cold plate 30. In some embodiments, the fins 80 are compressed toward one another after inserting the cold plate 30 to facilitate contact between the rejection surfaces 24 and the cold plate 30. By shaping the heat spreader 20 to form the cold plate slot 84 that receives the cold plate 30, the surface area of the heat spreader 20 that is in contact with the cold plate 30 is increased (e.g., doubled). This arrangement increases the heat transfer rate between the heat spreader 20 and the cold plate 30, thereby increasing the rate at which the thermal energy can be dissipated. The stacked arrangement of the fins 80 permits this increase in surface area without a substantial increase to the plan area (e.g., footprint) of the system 10, making the system 10 more compact.

In other embodiments, the cold plate 30 includes additional fins 80 coupled to the bridge 82, thereby forming additional cold plate slots 84. Each cold plate slot 84 may receive a different cold plate 30, such that the shape of the cold plate 30 permits the connection of multiple cold plates 30 with a single heat spreader 20. In yet other embodiments, the bridge 82 is omitted, and the system 10 includes an alternating stacked arrangement of cold plates 30 and separate heat spreaders 20, with each heat spreader 20 transferring thermal energy between two adjacent cold plates 30.

Referring to FIG. 14, the system 10 is shown according to an exemplary embodiment. In the embodiment of FIG. 14, the heat spreader 20 is shaped to include three fins 80 that are connected to one another by a pair of bridges 82. Each adjacent pair of fins 80 form a cold plate slot 84, such that the heat spreader 20 defines two total cold plate slots 84. The ends of the cold plate slots 84 are enclosed by the bridge 82, such that the cold plate slots 84 are each enclosed between the bridges 82 and the fins 80. Beneficially, the heat spreader 20 permits the use of two cold plates 30 with a single heat spreader 20.

### Connection Between Head Spreader and Cold Plate

In some embodiments, the connection between the heat spreader 20 and the cold plate 30 (e.g., engagement between the rejection surface 24 and the cold plate 30) is configured to minimize the thermal resistance to heat transfer between the heat spreader 20 and the cold plate 30. By minimizing the thermal resistance, the system 10 may maximize the amount of thermal energy that can dissipated by the system 10. As connections between two components may create a large thermal resistance, this area of the system 10 may have a significant impact on heat dissipation performance. The connections described herein may apply to the connections between any of the heat spreaders 20 and the cold plates 30 described herein (e.g., the systems 10 of FIGS. 1, 3, and 5-14).

In some embodiments, the heat spreader 20 and the cold plate 30 are connected using a thermal compound, thermal paste, or thermal grease. By way of example, the rejection surface 24 may include a layer or thermal grease, or a layer of thermal grease may be spread across the rejection surface 24, such that the thermal grease contacts both the rejection surface 24 and the cold plate 30. The thermal grease may decrease the thermal resistance between the heat spreader 20 and the cold plate 30 relative to an arrangement in which the heat spreader 20 contacts the cold plate 30 directly (e.g., due to imperfections in the surfaces that trap air or other contaminants that resist thermal conduction). In some embodiments, the connection between the heat spreader 20 and the cold plate 30 using thermal grease has a thermal resistance of about 3 (K cm²)/W.

In some embodiments, the heat spreader 20 and the cold plate 30 are connected by brazing. By way of example, the heat spreader 20 and the cold plate 30 may be manufactured separately. The rejection surface 24 may be pressed against the cold plate 30. The heat spreader 20 and the cold plate 30 may be heated, and a brazing compound may be applied to fixedly couple the heat spreader 20 to the cold plate 30. The brazing compound may decrease the thermal resistance between the heat spreader 20 and the cold plate 30 relative to an arrangement in which the heat spreader 20 contacts the cold plate 30 directly.

In some embodiments, the heat spreader heat spreader 20 and the cold plate 30 are connected by the rejection surface 24 with a surface of the cold plate 30. This bond may be formed using a wringing technique. By way of example, the rejection surface 24 and the corresponding surface of the cold plate 30 may be prepared by polishing the surfaces to a smooth and flat surface finish (e.g., by lapping) and oiling the surfaces. The surfaces are then pressed against one another in an arrangement that is angularly offset from a desired orientation. The heat spreader 20 and/or the cold plate 30 are then rotated until the surfaces reach the desired orientation (e.g., aligned with one another). This process may bond the heat spreader 20 and the cold plate 30 together at a molecular level, reducing the thermal resistance to heat transfer between the heat spreader 20 and the cold plate 30.

### Head Spreader and Cold Plate in Single Housing

Referring to FIG. 15-22, to further facilitate the transfer of thermal energy from the heat spreader 20 to the cold plate 30, the heat spreader 20 and the cold plate 30 may be formed from a single, continuous piece of material. In this way, a single piece of material may separate the fluid within the heat spreader 20 from the fluid within the cold plate 30 (e.g., a single piece of material extends continuously from the chamber of the heat spreader 20 to the chamber of the cold plate 30). In contrast, when the heat spreader 20 and the cold plate 30 are formed separately, the fluids are separated by a wall of the heat spreader 20, a wall of the cold plate 30, and any material between the walls (e.g., air, thermal grease, brazing material, etc.). The transitions between different materials may substantially increase the thermal resistance of the assembly, so removing these transitions may facilitate conduction. By way of example, thermal grease alone may have a thermal resistance of 0.3 (K cm²)/W, whereas an assembly using thermal grease to connect a heat spreader 20 and a cold plate 30 may have a thermal resistance of 3 (K cm²)/W, such that the transitions between different materials significantly increase the overall thermal resistance.

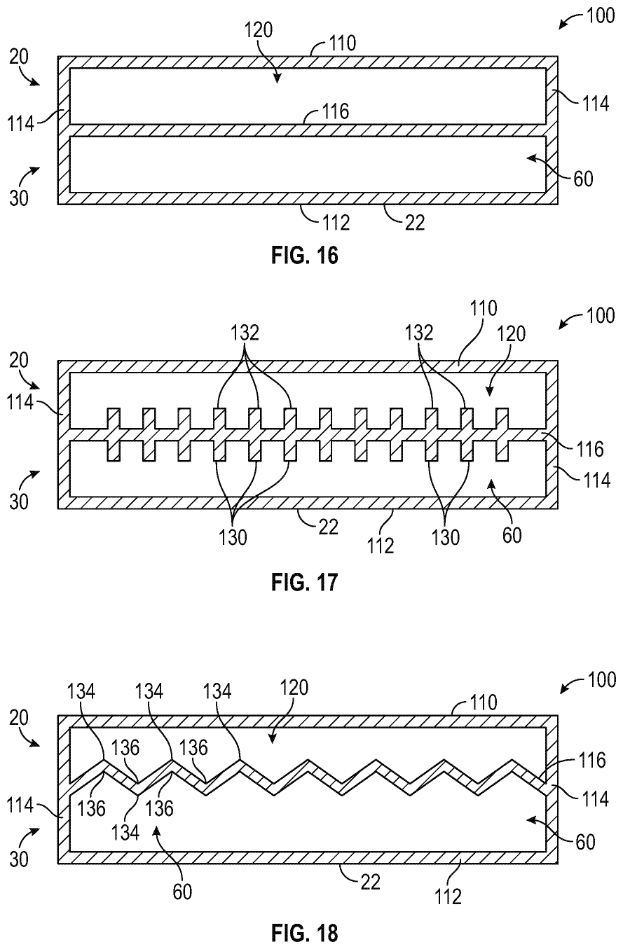

Referring to FIGS. 15 and 16, the system 10 is shown according to an exemplary embodiment. In the embodiment of FIGS. 15 and 16, the system 10 includes a housing, central portion, extrusion, or casting, shown as housing 100. Each end of the housing 100 may be fixedly coupled to a seal, shown as end cap 102. The end caps 102 may seal the housing 100, such that the housing 100 and the end caps 102 together form the heat spreader 20 and the cold plate 30. In some embodiments, the end caps 102 are formed separately from the housing 100 and subsequently coupled to the housing 100. In some such embodiments, the end caps 102 are removably coupled to the housing 100. Alternatively, one or both of the end caps 102 may be formed as part of a continuous piece with the housing 100.

The housing 100 may be manufactured using a variety of different methods. In some embodiments, the housing 100 is formed from extruded metal. In such embodiments, the housing 100 may have a continuous cross-sectional shape and size along a length of the housing 100. In other embodiments, the housing 100 is cast from metal. After initially forming the shape of the housing 100, material may be added (e.g., through welding or fastening) or removed (e.g., through drilling holes) to form the final shape of the housing 100.

As shown in FIGS. 15 and 16, the housing 100 includes a series of partitions, walls, members, or panels, shown as top wall 110, bottom wall 112 (e.g., a contact wall configured to engage a heat source), side walls 114, and dividing wall 116. In the embodiment of FIG. 16, the top wall 110, the bottom wall 112, the side walls 114, and the dividing wall 116 are fixedly coupled to one another and formed of a single, continuous piece of material. The top wall 110, the bottom wall 112, the side walls 114, and the dividing wall 116 may each engage and seal against the end caps 102. In other embodiments, the at least the dividing wall 116 is formed as a single, continuous piece of material that extends from the fluid chamber 60 to the fluid chamber 120, and other components of the housing 100 are formed as separate components and later coupled to the dividing wall 116.

The housing 100 defines a first chamber, passage, volume, or cold plate chamber, shown as fluid chamber 120, between the top wall 110, the dividing wall 116, and the side walls 114. The fluid chamber 120 may receive the fluid that acts as the heat-transfer medium in the coolant circuit 40 or the refrigeration circuit 50. Accordingly, the top wall 110, the dividing wall 116, the side walls 114, and the end caps 102 may serve as the cold plate 30. The housing 100 defines the fluid chamber 60 between the bottom wall 112, the dividing wall 116, and the side walls 114. Accordingly, the bottom wall 112, the dividing wall 116, the side walls 114, and the end caps 102 may serve as the heat spreader 20.

As shown, the housing 100 and the end caps 102 define a series of apertures, passages, ports, connections, or holes, shown as cooling fluid ports 122, that are in fluid communication with the fluid chamber 120. The fluid ports 122 may pass through the top wall 110, the side walls 114, and/or the end caps 102 to provide connections to the fluid chamber 120. The fluid ports 122 may facilitate adding fluid to the fluid chamber 120 (e.g., act as inlets), may facilitate removing fluid from the fluid chamber 120 (e.g., act as outlets), or may facilitate sensing a condition of the fluid (e.g., may act as sensing ports). By way of example, the fluid ports 122 may be formed by machining apertures in an extruded component or formed as an aperture in a cast component. In some embodiments, the fluid ports 122 are threaded to facilitate connection to other components (e.g., the heat exchanger 32, the supply line 34, the return line 36, the pump 38, the compressor 52, the expansion valve 54). By way of example, the fluid ports 122 may fluidly couple the fluid chamber 120 to a cooling circuit (e.g., the coolant circuit 40 or the refrigeration circuit 50).

The fluid ports 122 may be in fluid communication with other components through a variety of different components (e.g., flow control devices or connections). In some embodiments, one or more of the fluid ports 122 are in fluid communication with a quick connect connection, which facilitates selectively coupling the fluid ports 122 to another component (e.g., a hose or pipe). In some embodiments, one or more of the fluid ports 122 are in fluid communication with a relief valve (e.g., a refrigerant pressure relief valve) that permits fluid to exit the fluid chamber 120 when a pressure within the fluid chamber 120 exceeds a threshold pressure. In some embodiments, one or more of the fluid ports 122 are in fluid communication with a flow control valve that selectively limits fluid from entering or exiting the fluid chamber 120 (e.g., as operated by an electronic controller). In some embodiments, one or more of the fluid ports 122 are in fluid communication with fluid flow strainers (e.g., that straighten flow into or out of the fluid chamber 120, that filter out potential clogging debris prior to the fluid entering the cold plate 30, etc.). In some embodiments, one or more of the fluid ports 122 are in fluid communication with sensors, such as temperature sensors, flow meters, pressure sensors, or other types of sensors. By incorporating these components directly into the system 10, the system 10 may be plug and play device (e.g., a device capable of immediate use once installed). The sensors, valves, and other components may communicate with an electronic controller to facilitate diagnostics and control of the system 10.

As shown, the housing 100 and the end caps 102 define a series of apertures, passages, ports, connections, or holes, shown as heat transfer fluid ports 124, that are in fluid communication with the fluid chamber 60. The heat transfer fluid ports 124 may pass through the bottom wall 112, the side walls 114, and/or the end caps 102 to provide connections to the fluid chamber 60. The heat transfer fluid ports 124 may facilitate adding fluid to the fluid chamber 60 (e.g., act as inlets) during the initial assembly of the system 10. Subsequently, the heat transfer fluid ports 124 may be plugged or otherwise sealed. Alternatively, the heat transfer fluid ports 124 may be omitted, and the fluid chamber 60 may be filled with fluid before adding one of the end caps 102, then sealed by the end cap 102.

The dividing wall 116 acts as a barrier between the fluid chamber 120 and the fluid chamber 60, such that the heat transfer between the heat spreader 20 and the cold plate 30 passes through the dividing wall 116. As shown in FIG. 16, the dividing wall 116 is substantially flat. Accordingly, the surface area of the dividing wall 116 that is available for heat transfer between the heat spreader 20 and the cold plate 30 may be approximately equal to the footprint of the fluid chamber 120 and the fluid chamber 60.

Referring to FIG. 17, the housing 100 is shown according to an alternative embodiment. The housing 100 of FIG. 17 may be substantially similar to the housing 100 of FIG. 16, except as otherwise specified herein. The housing 100 of FIG. 17 includes a series of protrusions, flow control elements, fins, or ribs, shown as head spreader ribs 130 and cold plate ribs 132, that are fixedly coupled to the dividing wall 116. The heat spreader ribs 130 extend downward from the dividing wall 116 into the fluid chamber 60. The cold plate ribs 132 extend upward from the dividing wall 116 and into the fluid chamber 120. In embodiments where the housing 100 is formed as an extrusion, the heat spreader ribs 130 and the cold plate ribs 132 may be formed as part of a single piece with the rest of the housing 100. In such an embodiment, the heat spreader ribs 130 and the cold plate ribs 132 may have a constant cross-sectional shape along a length of the housing 100.

The heat spreader ribs 130 increase the surface area of the housing 100 that is exposed to the fluid chamber 60. Similarly, the cold plate ribs 132 increase the surface area of the housing 100 that is exposed to the fluid chamber 120. By increasing this surface area, the housing 100 may facilitate the transfer of thermal energy from the fluid chamber 60 to the fluid chamber 120. The heat spreader ribs 130 may provide areas that facilitate condensation of the fluid within the fluid chamber 60. The cold plate ribs 132 may guide flow of fluid through the fluid chamber 120 (e.g., straightening and increasing the uniformity of the flow).

Referring to FIG. 18, the housing 100 is shown according to an alternative embodiment. The housing 100 of FIG. 18 may be substantially similar to the housing 100 of FIG. 16, except as otherwise specified herein. In the housing 100 of FIG. 18, the dividing wall 116 is formed in a corrugated or zig-zag shape including a series of alternating protrusions, shown as peaks 134, and recesses, shown as valleys 136. The dividing wall 116 may be arranged such that a peak 134 exposed to the fluid chamber 120 is at the same lateral position of a valley 136 exposed to the fluid chamber 60. In embodiments where the housing 100 is formed as an extrusion, the dividing wall 116 may have a constant cross-sectional shape along a length of the housing 100.

The peaks 134 and the valleys 136 increase the surface area of the dividing wall 116 that is exposed to the fluid chamber 60 and the fluid chamber 120. By increasing this surface area, the housing 100 may facilitate the transfer of thermal energy from the fluid chamber 60 to the fluid chamber 120. The peaks 134 exposed to the fluid chamber 60 may provide areas that facilitate condensation of the fluid within the fluid chamber 60. The peaks 134 and the valleys 136 exposed to the fluid chamber 120 may guide flow of fluid through the fluid chamber 120 (e.g., straightening and increasing the uniformity of the flow).

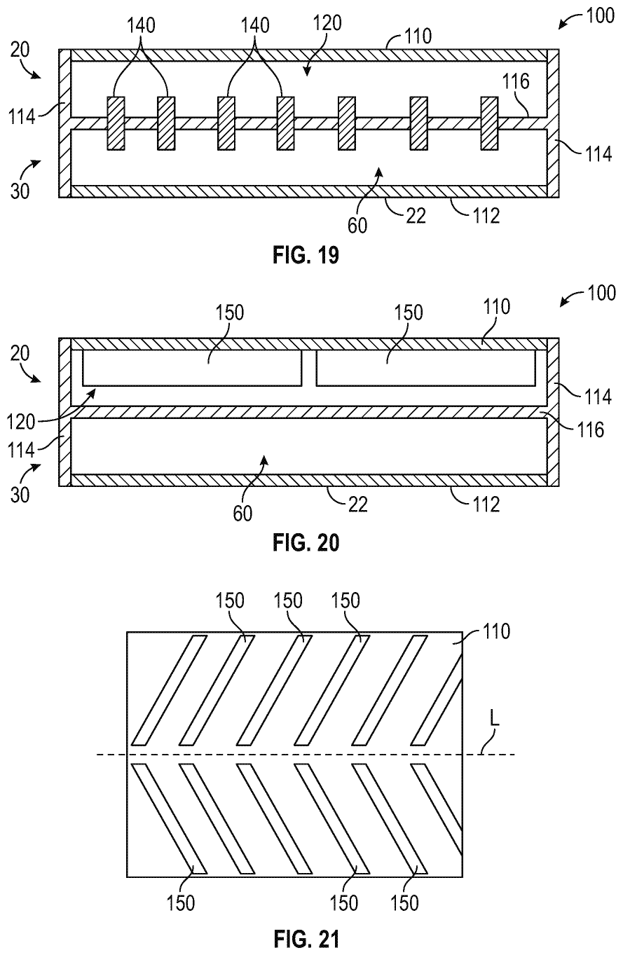

Referring to FIG. 19, the housing 100 is shown according to an alternative embodiment. The housing 100 of FIG. 19 may be substantially similar to the housing 100 of FIG. 16, except as otherwise specified herein. In the housing 100 of FIG. 19, the top wall 110 and the bottom wall 112 are formed separately from the side walls 114 and the dividing wall 116. Accordingly, the top wall 110 and the bottom wall 112 may be coupled to the side walls 114 after the housing 100 is initially manufactured. This may facilitate access to the dividing wall 116 to perform surface modifications after the housing 100 is extruded or otherwise manufactured.

As shown in FIG. 19, the system 10 further includes a series of posts, protrusions, pins, or inserts, shown as pins. The pins 140 are inserted through the dividing wall 116, such that the pins 140 extend into the fluid chamber 120 and the fluid chamber 60. By way of example, a series of holes or apertures may be drilled into the dividing wall 116, and the pins 140 may be pressed into the holes. After insertion of the pins 140, the top wall 110 and the bottom wall 112 may be fixedly coupled to the side walls 114, covering the pins 140.

The pins 140 add surface area that is exposed to the fluid chamber 60 and the fluid chamber 120. By increasing this surface area, the housing 100 may facilitate the transfer of thermal energy from the fluid chamber 60 to the fluid chamber 120. The portions of the pins 140 that are exposed to the fluid chamber 60 may provide areas that facilitate condensation of the fluid within the fluid chamber 60. The portions of the pins 140 that are exposed to the fluid chamber 120 may guide flow of fluid through the fluid chamber 120.

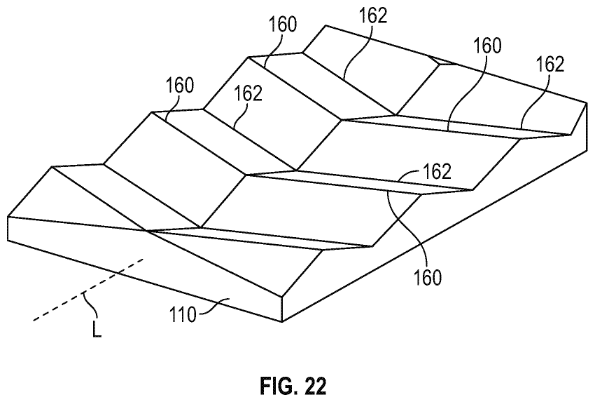

Referring to FIGS. 20 and 21, the housing 100 is shown according to an alternative embodiment. The housing 100 of FIGS. 20 and 21 may be substantially similar to the housing 100 of FIG. 16, except as otherwise specified herein. In the housing 100 of FIGS. 20 and 21, the top wall 110 and the bottom wall 112 are formed separately from the side walls 114 and the dividing wall 116. Accordingly, the top wall 110 and the bottom wall 112 may be coupled to the side walls 114 after the housing 100 is initially manufactured. This may facilitate access to the dividing wall 116 to perform surface modifications after the housing 100 is extruded or otherwise manufactured.

The housing 100 includes a series of protrusions, flow control elements, fins, or ribs, shown as chevron ribs 150, that are fixedly coupled to the top wall 110. By way of example, the top wall 110 and the chevron ribs 150 may be formed from a single, continuous piece of material. The chevron ribs 150 extend downward from the top wall 110 and into the fluid chamber 120. As shown, the chevron ribs 150 are angled such that the chevron ribs 150 extend longitudinally rearward as the chevron ribs 150 extend laterally outward from a longitudinal centerline L of the top wall 110. The chevron ribs 150 may guide flow of fluid through the fluid chamber 120. By forming the top wall 110 separately from the side walls 114, the chevron ribs 150 may be formed on the top wall 110 (e.g., through machining or casting) before the chevron ribs 150 are inserted into the fluid chamber 120, simplifying the process of manufacturing the housing 100.

FIG. 22 illustrates an alternative embodiment of the top wall 110 that utilizes a different chevron arrangement. The top wall 110 of FIG. 22 may be used in place of the top wall 110 of FIG. 21. The top wall 110 of FIG. 22 has a surface that forms a corrugated or zig-zag shape including a series of alternating protrusions, shown as peaks 160, and recesses, shown as valleys 162. As shown in FIG. 22, the peaks 160 and the valleys 162 are formed in an angled chevron pattern, such that the peaks 160 and the valleys 162 extend longitudinally rearward as the peaks 160 and the valleys 162 extend laterally outward from a longitudinal centerline L of the top wall 110.

### Carbon Dioxide Configuration

Referring to FIGS. 1 and 3, in some embodiments, the system 10 is configured to utilize carbon dioxide as a heat transfer fluid that circulates through the coolant circuit 40 or the refrigeration circuit 50. Accordingly, the carbon dioxide may act as a coolant or refrigerant, removing thermal energy from the cold plate 30 to cool the heat source 12. In some embodiments, the carbon dioxide is in a gaseous state when passing through at least a portion of the cold plate 30 (e.g., the carbon dioxide changes from a liquid to a gas within the cold plate 30, the carbon dioxide is a gas when entering the cold plate 30, etc.).

In some embodiments, the system 10 of FIG. 1 utilizes the carbon dioxide as a heat transfer medium or heat transfer fluid within the coolant circuit 40. In some such embodiments, the pump 38 is positioned along the return line 36 (e.g., as shown in dashed lines in FIG. 1). In operation, the carbon dioxide may begin within the return line 36 as a liquid and may be moved along the return line 36 by the pump 38. Upon entering the cold plate 30, the carbon dioxide may receive thermal energy from the cold plate 30 and be converted to a gas. The carbon dioxide may pass along the supply line 34 to the heat exchanger 32. Within the heat exchanger 32, the carbon dioxide may be cooled and return to a liquid state. This cycle may be repeated as the carbon dioxide flows through the coolant circuit 40.

In some embodiments, the system 10 of FIG. 3 utilizes the carbon dioxide as a heat transfer medium or heat transfer fluid within the refrigeration circuit 50. In operation, the compressor 52 forces the carbon dioxide to circulate throughout the refrigeration circuit 50 to perform a refrigeration cycle and cool the cold plate 30. The cold plate 30 receives a volume of carbon dioxide as a low-pressure liquid from the return line 36. The cold plate 30 transfers thermal energy to the carbon dioxide, converting the carbon dioxide to a low-pressure gas and cooling the cold plate 30. The carbon dioxide passes to the compressor 52, where the carbon dioxide is compressed to a high pressure. The high-pressure gas is received by the heat exchanger 32 (e.g., configured as a condenser), and the heat exchanger 32 transfers thermal energy from the carbon dioxide to the surrounding environment. The carbon dioxide leaves the heat exchanger 32 as a high-pressure liquid and passes to the expansion valve 54. The expansion valve 54 expands the carbon dioxide, returning the carbon dioxide back to the cold plate 30 as a low-pressure liquid.

### System Reinforcement for High-Pressure Heat Transfer Fluids

Referring to FIG. 1-5, in some embodiments, the heat transfer fluid passes through the cold plate 30 at a high pressure. By way of example, when using carbon dioxide as the heat transfer fluid, the pressure of the carbon dioxide may exceed 1000 psi when the carbon dioxide is within the cold plate 30. This high pressure may facilitate significant heat transfer, but the pressurized carbon dioxide may impart significant stresses onto the cold plate 30, which act to deform the cold plate 30 and the heat spreader 20. If the stresses are significant enough to deform the conduction surface 22, contact between the heat source 12 and the heat spreader 20 may be reduced, inhibiting heat transfer and reducing cooling performance. Accordingly, it is advantageous to permit the use of high-pressure gasses within the cold plate 30 while also minimizing deformation of the conduction surface 22.

By way of example, in the embodiment shown in FIG. 16, the carbon dioxide within the fluid chamber 120 may press outward against the top wall 110, the side walls 114, and the dividing wall 116. The pressure may cause the top wall 110 and the side walls 114 to bow outward and may cause the dividing wall 116 to bow downward toward the bottom wall 112. If the side walls 114 bow outward, the connections between the side walls 114 and the bottom wall 112 may impart a torque onto the bottom wall 112, causing the bottom wall 112 to bend. Bending of the bottom wall 112 may warp the conduction surface 22 along the bottom of the bottom wall 112, decreasing the contact area between the conduction surface 22 and the heat source 12.

In some embodiments, deformation of the bottom wall 112 is resisted or reduced (e.g., prevented) by adding features to strengthen the heat spreader 20 and/or the cold plate 30. These features may support the top wall 110, the bottom wall 112, the side walls 114, and/or the dividing wall 116 to reduce deformation of the housing 100. In some embodiments, the features are formed as part of an extrusion along with other portions of the housing 100. In other embodiments, the features are formed separately from one or more of the walls and subsequently coupled to the housing 100 (e.g., through a press fit, using welding, using an adhesive, etc. In yet other embodiments, the housing 100 is formed through an additive manufacturing operation (e.g., a selective laser sintering 3D printing operation or other method of 3D printing metal). Beneficially, additive manufacturing techniques may facilitate forming complex shapes. These techniques may be used to form any of the structures described herein.

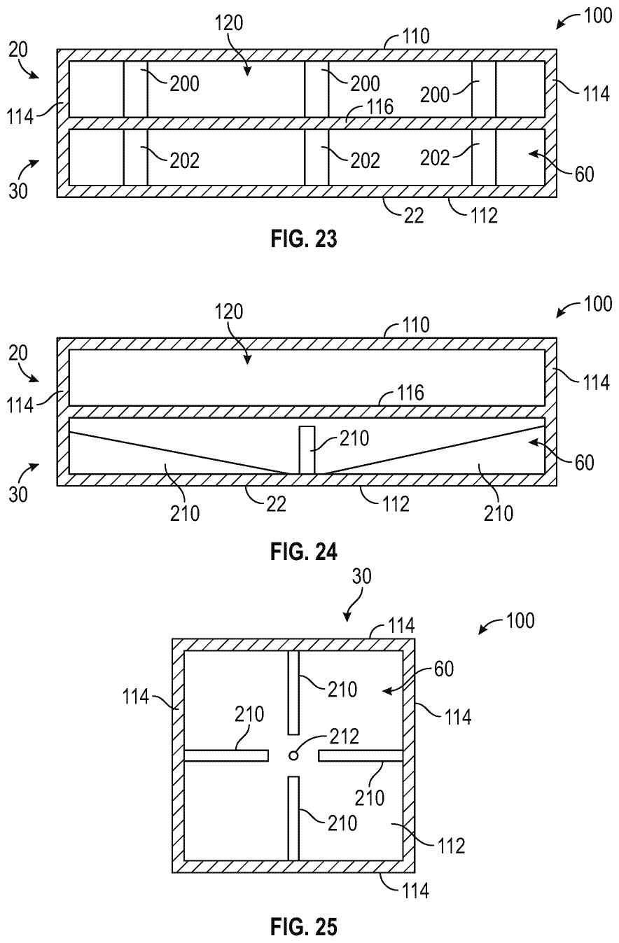

Referring to FIG. 23, the housing 100 is shown according to an alternative embodiment. The housing 100 of FIG. 23 may be substantially similar to the housing 100 of FIG. 16, except as otherwise specified herein. The housing 100 of FIG. 23 includes a series of support features, supports, stabilizing structures, stilts, protrusions, or columns, shown as support columns 200 and support columns 202. The support columns 200 are fixedly coupled to and extend between the dividing wall 116 and the top wall 110. The support columns 200 and the support columns 202 may be integrally formed with the top wall 110, the bottom wall 112, and/or the dividing wall 116 as a single, continuous piece or formed separately and coupled to the housing 100. The support columns 202 are fixedly coupled to and extend between the dividing wall 116 and the bottom wall 112. In some embodiments, the support columns 200 and the support columns 202 extend substantially vertically. The support columns 200 and the support columns 202 may have a circular cross section, a square cross section, or a different cross-sectional shape.

In some embodiments, the housing 100 includes more or fewer support columns 200 and/or support columns 202. In other embodiments, the support columns 200 are omitted, and the housing 100 includes only the support columns 202. In yet other embodiments, the support columns 202 are omitted, and the housing 100 includes only the support columns 200.

The support columns 200 are spaced from one another within the fluid chamber 120 to facilitate fluid flow through the fluid chamber 120. By way of example, carbon dioxide may flow between the support columns 200. Similarly, the support columns 202 are spaced from one another within the fluid chamber 60 to facilitate fluid flow through the fluid chamber 60. By way of example, heat transfer fluid 62 may freely flow downward along the support columns 202 from the dividing wall 116 to the bottom wall 112 as the heat transfer fluid 62 condenses. Accordingly, the addition of the support columns 200 and the support columns 202 may still permit fluid flow to transfer thermal energy through the housing 100.

Beneficially, the support columns 200 and the support columns 202 increase the strength of the housing 100 to resist deformation of the bottom wall 112 when the fluid chamber 120 experiences high pressures. The support columns 200 resist movement of the top wall 110 relative to (e.g., toward, away from, etc.) the dividing wall 116. Accordingly, the support columns 200 facilitate maintaining a desired shape of the cold plate 30, reducing the forces experienced by the heat spreader 20. The support columns 202 resist movement of the bottom wall 112 relative to (e.g., toward, away from, etc.) the dividing wall 116. Accordingly, the support columns 202 facilitate maintaining a desired shape of the heat spreader 20, resisting the forces imparted on the heat spreader 20 by the cold plate 30.

Referring to FIGS. 24 and 25, the housing 100 is shown according to an alternative embodiment. The housing 100 of FIGS. 24 and 25 may be substantially similar to the housing 100 of FIG. 23, except as otherwise specified herein. The housing 100 of FIGS. 24 and 25 includes a series of support features, supports, stabilizing structures, fins, protrusions, or ribs, shown as support ribs 210. In other embodiments, the housing 100 includes more or fewer support ribs 210.

The support ribs 210 are fixedly coupled to and extend from the bottom wall 112 to the side walls 114. As shown, the support ribs 210 extend upward from the bottom wall 112 and radially inward from the side walls 114 toward a central vertical axis 212 of the housing 100. By placing the support ribs 210 within the fluid chamber 60 as opposed to on a lower side of the bottom wall 112, the support ribs 210 are prevented from interfering with contact between the bottom wall 112 and the heat source 12. The support ribs 210 are angularly offset from one another about the central vertical axis 212, providing spaces between adjacent support ribs 210. These spaces may facilitate the refrigerant flowing back toward the central vertical axis 212 and the heat source 12 as the phase change cycle of the refrigerant within the heat spreader 20 is completed.

The support ribs 210 have a changing height, such that the top surfaces of the support ribs 210 are sloped. Specifically, the support ribs 210 have a first height at the side walls 114 and a second height at an opposing end nearest the central vertical axis 212. The second height is less than the first height, such that the support ribs 210 slope downward toward the central vertical axis 212. This downward slope may facilitate the refrigerant flowing back toward the central vertical axis 212 and the heat source 12 as the phase change cycle of the refrigerant within the heat spreader 20 is completed.

Beneficially, support ribs 210 increase the strength of the housing 100 to resist deformation of the bottom wall 112 when the fluid chamber 120 experiences high pressures. The support ribs 210 extend along the bottom wall 112 and upward from the bottom wall 112, resisting bending of the bottom wall 112. Additionally, the support ribs 210 extend upward along the side walls 114, resisting bending of the side walls 114. Accordingly, the support ribs 210 facilitate maintaining a desired shape of the heat spreader 20, resisting the forces imparted on the heat spreader 20 by the cold plate 30. In some embodiments, the housing 100 further includes one or more support columns 200 and/or support columns 202 in addition to the support ribs 210.

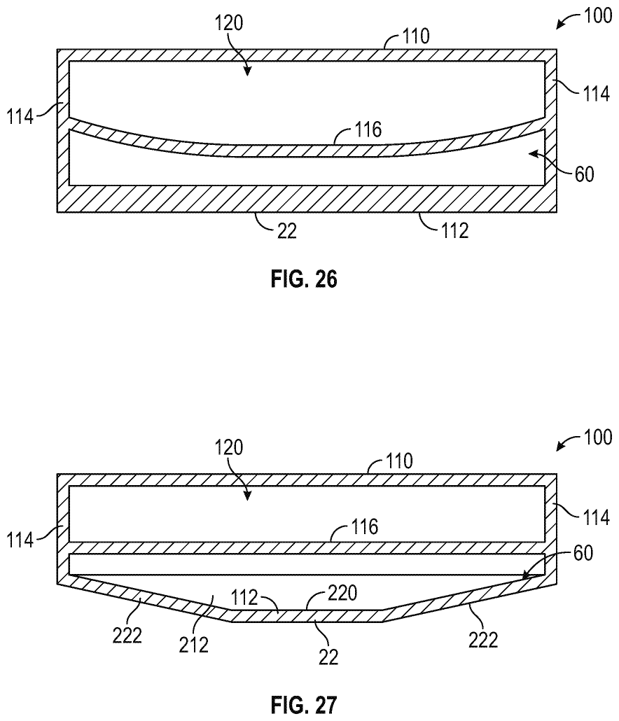

Referring to FIG. 26, the housing 100 is shown according to an alternative embodiment. The housing 100 of FIG. 26 may be substantially similar to the housing 100 of FIG. 16, except as otherwise specified herein. The housing 100 of FIG. 26 is configured such that the bottom wall 112 has a greater rigidity than the top wall 110, the side walls 114, and the dividing wall 116. Accordingly, the top wall 110, the side walls 114, and the dividing wall 116 may be more flexible than the bottom wall 112.

For the purposes of maximizing heat transfer between the heat source 12 and the heat transfer fluid 62, the primary consideration is the contact between the conduction surface 22 and the bottom wall 112 and the heat source 12. Accordingly, if the bottom wall 112 is prevented from bending, the other portions of the housing 100 may be deformed without impacting heat transfer through the bottom wall 112. By way of example, pressurized carbon dioxide within the fluid chamber 120 may cause the top wall 110, the side walls 114, and the dividing wall 116 to bow outward without impacting heat transfer through the bottom wall 112, as long as the bottom wall 112 resists bending.

In view of this, the housing 100 may be constructed such that the rigidity of the top wall 110, the side walls 114, and the dividing wall 116 is less than that of the bottom wall 112. By way of example, the dividing wall 116 is shown in FIG. 26 to be bending, whereas the bottom wall 112 is straight and rigid. In some embodiments, the rigidity of a wall is controlled by increasing or decreasing the thickness of the wall relative to other walls of the housing 100. By way of example, the rigidity of the bottom wall 112 may be increased by increasing the thickness of the bottom wall 112 relative to the other walls, as shown in FIG. 26 (e.g., such that a first thickness of the bottom wall 112 is greater than a second thickness of the dividing wall 116). In some embodiments, the rigidity of a wall is controlled by using different materials in different walls of the housing 100. By way of example, the bottom wall 112 may utilize a more rigid material than the side walls 114. In some embodiments, the rigidity of a wall is controlled based on the shape of the wall. By way of example, the dividing wall 116 may be formed with pleats, folds, or a bellows structure (e.g., as shown in FIG. 18) to make the dividing wall 116 more flexible. The housing 100 may employ any of these strategies to control the relative flexibility of each of the walls of the housing 100.

Referring to FIG. 27, the housing 100 is shown according to an alternative embodiment. The housing 100 of FIG. 27 may be substantially similar to the housing 100 of FIG. 16, except as otherwise specified herein. The bottom wall 112 of the housing 100 of FIG. 27 includes first section, horizontal section, or flat section, shown interface section 220, and a series of angled sections 222. The interface section 220 extends horizontally and defines the conduction surface 22. The angled sections 222 extend outward from the interface section 220 toward the side walls 114. Each of the angled sections 222 extends upward as the angled section 222 extends outward (i.e., extends downward and laterally toward the interface section 220), such that the angled sections 222 are sloped upward. Accordingly, the angled sections 222 and the interface section 220 form a pyramid frustrum. In other embodiments, the bottom wall 112 includes more or fewer angled sections 222 (e.g., two angled sections 222).

By angling the angled sections 222, the bottom wall 112 slopes downward until the bottom wall 112 reaches the interface section 220. This sloped configuration directs fluid within the fluid chamber 60 toward the heat source 12, facilitating the heat transfer cycle within the heat spreader 20. By way of example, fluid may collect along the interface section 220 and be heated by the heat source 12 to form a vapor. The vapor may condense along the dividing wall 116, forming a liquid. The liquid may fall onto the angled sections 222, which direct the liquid back to the interface section 220 through the action of gravity on the sloped surfaces. Accordingly, the liquid is automatically brought back toward the hottest portion of the bottom wall 112, facilitating heat transfer.

As utilized herein with respect to numerical ranges, the terms “approximately,” “about,” “substantially,” and similar terms generally mean +/−10% of the disclosed values. When the terms “approximately,” “about,” “substantially,” and similar terms are applied to a structural feature (e.g., to describe its shape, size, orientation, direction, etc.), these terms are meant to cover minor variations in structure that may result from, for example, the manufacturing or assembly process and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

The hardware and data processing components used to implement the various processes, operations, illustrative logics, logical blocks, modules and circuits described in connection with the embodiments disclosed herein may be implemented or performed with a general purpose single-or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some embodiments, particular processes and methods may be performed by circuitry that is specific to a given function. The memory (e.g., memory, memory unit, storage device) may include one or more devices (e.g., RAM, ROM, Flash memory, hard disk storage) for storing data and/or computer code for completing or facilitating the various processes, layers and modules described in the present disclosure. The memory may be or include volatile memory or non-volatile memory, and may include database components, object code components, script components, or any other type of information structure for supporting the various activities and information structures described in the present disclosure. According to an exemplary embodiment, the memory is communicably connected to the processor via a processing circuit and includes computer code for executing (e.g., by the processing circuit or the processor) the one or more processes described herein.

The present disclosure contemplates methods, systems and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It is important to note that the construction and arrangement of the system 10 as shown in the various exemplary embodiments is illustrative only. Additionally, any element disclosed in one embodiment may be incorporated or utilized with any other embodiment disclosed herein. For example, the heat spreader 20 of the exemplary embodiment shown in at least FIG. 4 may be incorporated in the system 10 of the exemplary embodiment shown in at least FIG. 1. Although only one example of an element from one embodiment that can be incorporated or utilized in another embodiment has been described above, it should be appreciated that other elements of the various embodiments may be incorporated or utilized with any of the other embodiments disclosed herein.

What is claimed is:

1. A thermal management system comprising:
a heat source configured to provide thermal energy;
a cooling circuit configured to deliver a first heat transfer fluid; and
a housing including a contact wall engaging the heat source and a dividing wall offset from the contact wall, the housing defining:
a heat spreader chamber extending from the contact wall to the dividing wall and containing a second heat transfer fluid;
a cold plate chamber separated from the heat spreader chamber by the dividing wall; and
a fluid aperture fluidly coupling the cold plate chamber to the cooling circuit,
wherein the second heat transfer fluid is configured to transfer the thermal energy from the heat source to the first heat transfer fluid within the cold plate chamber; and
wherein the dividing wall extends continuously from the heat spreader chamber to the cold plate chamber.

2. The thermal management system of claim 1, wherein the housing further includes a side wall extending away from the dividing wall, and wherein the side wall and the dividing wall are formed as a single, continuous piece of material.

3. The thermal management system of claim 2, wherein the side wall partially defines the heat spreader chamber.

4. The thermal management system of claim 3, wherein the side wall, the dividing wall, and the contact wall are formed as the single, continuous piece of material.

5. The thermal management system of claim 2, wherein the side wall partially defines the cold plate chamber.

6. The thermal management system of claim 5, wherein the housing further includes a top wall offset from the dividing wall, wherein the cold plate chamber extends from the top wall to the dividing wall, and wherein the side wall, the dividing wall, and the contact wall are formed as the single, continuous piece of material.

7. The thermal management system of claim 2, further comprising an end cap coupled to the housing and partially defining the heat spreader chamber and the cold plate chamber.

8. The thermal management system of claim 2, wherein the housing further includes a top wall offset from the dividing wall, wherein the cold plate chamber extends from the top wall to the dividing wall, wherein the side wall extends from the top wall to the contact wall, and wherein the side wall, the dividing wall, the contact wall, and the top wall are formed as the single, continuous piece of material.

9. The thermal management system of claim 1, wherein the contact wall has a first thickness, and wherein the dividing wall has a second thickness less than the first thickness.

10. The thermal management system of claim 1, wherein the contact wall is positioned below the dividing wall, and wherein the contact wall includes an interface section that engages the heat source and an angled section that extends upward and laterally outward from the interface section.

11. A thermal management system comprising:
a heat source configured to provide thermal energy;
a heat spreader including a contact wall engaging the heat source, the heat spreader defining a heat spreader chamber containing a first heat transfer fluid;
a cold plate coupled to the heat spreader and defining a cold plate chamber configured to be fluidly coupled to a cooling circuit such that the first heat transfer fluid transfers the thermal energy from the heat source to a second heat transfer fluid within the cold plate chamber;
a dividing wall extending between the heat spreader chamber and the cold plate chamber; and
a protrusion extending into the heat spreader chamber.

12. The thermal management system of claim 11, wherein the protrusion is coupled to the dividing wall and extends toward the contact wall.

13. The thermal management system of claim 12, wherein the protrusion is a support column extending across the heat spreader chamber from the dividing wall to the contact wall.

14. The thermal management system of claim 12, wherein the protrusion is a first protrusion, further comprising a second protrusion coupled to the dividing wall and extending into the cold plate chamber.

15. The thermal management system of claim 14, wherein the cold plate includes a top wall opposite the dividing wall, and wherein the second protrusion extends across the cold plate chamber from the dividing wall to the contact wall.

16. The thermal management system of claim 11, wherein the protrusion is coupled to the contact wall and extends toward the dividing wall.

17. The thermal management system of claim 16, wherein the heat spreader further includes a side wall extending between the contact wall and the dividing wall, and wherein the protrusion is a rib extending from the side wall into the heat spreader chamber.

18. The thermal management system of claim 11, wherein the dividing wall is formed as a single, continuous piece of material that partially defines both the heat spreader chamber and the cold plate chamber.

19. A thermal management system comprising:
a heat source configured to provide thermal energy;
a cooling circuit configured to deliver a first heat transfer fluid;
a heat spreader engaging the heat source and containing a second heat transfer fluid;
a cold plate including a first wall coupled to the heat spreader, a second wall offset from the first wall to define a fluid chamber fluidly coupled to the cooling circuit such that the second heat transfer fluid is configured to transfer the thermal energy from the heat source to the first heat transfer fluid within the fluid chamber; and
a protrusion coupled to the first wall and extending into the fluid chamber toward the second wall.

20. The thermal management system of claim 19, wherein the protrusion is a support column extending across the fluid chamber from the first wall to the second wall.
